(19) United States
(12) Patent Application Publication
(10) Pub. No.: US 2005/0006639 A1
(43) Pub. Date: Jan. 13, 2005

(54) Semiconductor electronic devices and methods

(76) Inventors: Russell D. Dupuis, Atlanta, GA (US); Uttiya Chowdhury, Scottsdale, AZ (US)

Correspondence Address: MEYERTONS, HOOD, KIVLIN, KOWERT & GOETZEL, P.C., P.O. BOX 398, AUSTIN, TX, 78767-0398, US

(21) Appl. No.: 10/852,693

(22) Filed: May 24, 2004

Related U.S. Application Data
(60) Provisional application No. 60/472,970, filed on May 23, 2003.

(51) Int. Cl. H01L 31/0328; H01L 21/336

(52) U.S. Cl. 257/20; 257/24; 438/590; 257/192; 438/285

(57) ABSTRACT

Embodiments disclosed herein include electronic device designs based upon electronic properties of Group III-N materials and quantum-mechanical effects of specialized heterostructures. Such electronic device designs may include, for example, heterojunction field-effect transistors (HFETs) and high-electron-mobility transistors (HEMTs). The design concepts permit high power, high-frequency, and high-temperature operation of advanced electronic circuits, including devices for radar, collision-avoidance systems, and wireless communications. Designs disclosed may include one or more AlN layers and/or one or more SMASH superlattice barriers combined with one or more n-type delta-doped regions. Alternately, in certain embodiments, one or more AlN layers and one or more SMASH superlattice barriers may be combined without the n-type delta-doped regions.

### PRIORITY CLAIM

This application claims the benefit of U.S. Provisional Application No. 60/472,970 entitled “SEMICONDUCTOR ELECTRONIC DEVICES AND METHODS,” filed May 23, 2003.

### BACKGROUND OF THE INVENTION

1. Field of the Invention

Embodiments disclosed herein generally relate to semiconductor devices. More particularly, embodiments relate to transistors having certain desired properties and methods of manufacturing such transistors.

2. Description of the Relevant Art

During the past few years, there has been interest in the use of wide-bandgap semiconductors, e.g., SiC and GaN, for applications in high-power and high-temperature electronic devices (e.g., p-i-n rectifiers, heterojunction bipolar transistors (HBTs), heterojunction field-effect transistors (HFETs), and Schottky barriers). For some applications, GaN devices are predicted to out-perform Si and SiC devices for power applications. Consequently, Group III-nitride materials are receiving attention for high-power electronic applications owing to their promising material properties. While there have recently been demonstrations of Group III-V nitride-based HFETs, to date, power devices performing at or near the theoretical limits for GaN do not appear to have been reported.

It is believed that microwave power devices based on GaAs have almost reached their power limits, whereas the needs for higher microwave power densities are increasing. One of the possibilities for improving power performance at X-band and higher frequencies is to use new material systems. Group III-nitride materials may be attractive for high-power and high-temperature devices because of their intrinsic properties: large energy bandgap, high breakdown voltage, and high peak electron velocity. Microwave power devices such as AlGaN/GaN HEMTs have demonstrated impressive output power density, greater than those of GaAs. For microwave power high electron mobility transistors (HEMTs), a high current gain cut off frequency along with a high saturation current may be desirable. A high drain current of 1,500 mA/mm with a transconductance of 300 mS/mm has been reported with a classic modulation-doped HEMT structure.

### SUMMARY OF THE INVENTION

AlGaN/GaN HFETs may be candidates for future applications in high power, high-frequency, high power, and high-temperature electronics (e.g., BMD-class X-band radar systems) because of the fundamental characteristics of Group III-nitride materials. For example, in certain embodiments, a transistor having desired performance characteristics may include one or more AlN layers and/or one or more SMASH superlattice barriers combined with one or more n-type delta-doped regions. Alternately, in certain embodiments, one or more AlN and one or more SMASH superlattice barriers may be combined without the n-type delta-doped regions.

### BRIEF DESCRIPTION OF THE DRAWINGS

Other objects and advantages of the invention will become apparent upon reading the following detailed description and upon reference to the accompanying drawings in which:

FIG. 1a: depicts a schematic diagram of an energy-band diagram for a SMASH in the InAlP/InGaP materials system, according to an embodiment;

FIG. 1b: depicts a schematic diagram of an energy-band diagram for multiple-quantum barrier in the InAlP/InGaP materials system, according to an embodiment;

FIG. 2a: depicts a schematic diagram of a SMASH barrier HFET structure showing superlattice charge layers with an AlN barrier, according to an embodiment;

FIG. 2b: depicts a schematic expanded view of the conduction band structure of an AlN/AlxGal-xN SMASH barrier for enhanced carrier confinement in the channel, according to an embodiment;

FIG. 3: depicts a diagram of drain current to drain voltage for a D²B² AlGaN/AlN/GaN HFET, according to one embodiment;

FIG. 4: depicts a diagram transconductance to gate voltage for a D²B² AlGaN/AlN/GaN HFET, according to one embodiment;

FIG. 5: depicts a diagram of drain current to drain voltage for a D²B² AlGaN/AlN/GaN HFET, according to one embodiment;

FIG. 6: depicts a diagram of current gain to frequency for a D²B² AlGaN/AlN/GaN HFET, according to one embodiment;

FIG. 7: depicts a diagram of minimum noise and associated gain to frequency for a D₂B² AlGaN/AlN/GaN HFET, according to one embodiment;

FIG. 8: depicts a diagram of drain current to drain voltage for a D²B² AlGaN/AlN/GaN HFET, according to one embodiment;

FIG. 9: depicts a diagram of drain current and gₘ to gate voltage for a D²B² AlGaN/AlN/GaN HFET, according to one embodiment;

FIG. 10: depicts a diagram frequency response for a D²B² AlGaN/AlN/GaN HFET, according to one embodiment;

FIG. 11: depicts a diagram of drain current to drain voltage for a D²B² AlGaN/AlN/GaN HFET, according to one embodiment;

FIG. 12: depicts a diagram of drain current and gₘ to gate voltage for a D²B² AlGaN/AlN/GaN HFET, according to one embodiment;

FIG. 13: depicts a HFET with AlN barrier and delta-doped charge layer, according to an embodiment;

FIG. 14: depicts a HFET with AlN/GaN superlattice charge and buffer layer, according to an embodiment; and

FIG. 15: depicts a HFET with SMASH barrier layer, according to an embodiment.

While the invention is susceptible to various modifications and alternative forms, specific embodiments thereof are shown by way of example in the drawings and will herein be described in detail. It should be understood, however, that the drawing and detailed description thereto are not intended to limit the invention to the particular form disclosed, but on the contrary, the intention is to cover all modifications, equivalents and alternatives falling within the spirit and scope of the present invention as defined by the appended claims.

### DETAILED DESCRIPTION OF THE PREFERRED EMBODIMENTS

In an embodiment, AlGaN/GaN heterojunction field-effect transistors (HFETs) may be used in high-power, high-frequency, and high-temperature electronics, because of the fundamental characteristics of Group III-nitride materials. Improved high-power HFET performance has been recently achieved and a power density of 10.7 W/mm at 10 GHz has been demonstrated. For high-power device applications, a high drain-source current, I_{DS}, along with a high transconductance and a large source-drain breakdown voltage may be desirable.

In an embodiment, a large source-drain current, I_{DS}, may be achieved if the sheet charge density, nₛ, the carrier mobility, μₙ, and the saturation drift velocity, vₛ, in the channel have relatively large values. Currently, a large source-drain current may be achieved by using undoped or modulation-doped AlGaN/GaN structures. Another method of achieving a large source-drain current may include increasing the aluminum mole fraction (and therefore, the bandgap) in an AlGaN barrier. Although, increasing the Al mole fraction in the AlGaN cap layer may lead to higher nₛ, it may also lead to a decrease in μₙ. As a result, nₛμₙ product improvement may be limited.

Large source-drain current devices may be referred to as “high-electron mobility transistors” or HEMTs. Recently, the use of a binary barrier of AlN was reported to increase the low-field electron mobility, μₙ, and nₛ in the channel, yielding an nₛ μₙ product of 2.28×10¹⁶ V-s. However, the FET device performance (e.g., I_{DSmax} and gₘ) did not appear to be improved compared to the performance achieved by a “standard” modulation-doped HFET.

Embodiments disclosed herein include delta-doped heterostructure FET designs. Such designs may include the use of one or more AlN barriers. Additionally, one or more superlattice barriers may be included in delta-doped heterostructure FET designs disclosed herein. One or more AlN and/or one or more superlattice barriers may be combined with one or more n-type delta-doped regions. Alternately, in certain embodiments, one or more AlN and one or more superlattice barriers may be combined without the n-type delta-doped regions. In embodiments that include n-type delta-doped regions, the n-type delta-doped regions may improve the current carrying capabilities of the HFET. In certain embodiments, n-type delta-doped regions have the additional benefits of reduced gate leakage, low noise, high gₘ, and capability of sustaining a large voltage across the drain source region (large V_{DS}) prior to breakdown of the device. The structures described above may demonstrate relatively high nₛ μₙ product, relatively large drain currents, relatively high values of extrinsic transconductance, relatively low noise figures at 17 GHz, and/or transconductance values close to the state-of-the-art.

An superlattice heterostructure includes a series of alternating layers of smaller-bandgap “quantum well layer” and larger-bandgap “barrier layers.” Quantum mechanics predicts that an electron has a non-zero reflection probability from a barrier lower than the energy of the electron. With appropriate design of the barriers and wells, the reflected wave may be made to interfere destructively with the incident electron wave. A propagation matrix is calculated for each interface that calculates the ratio of incident wave, reflected wave and transmitted wave. For a multi-period heterostructure, these propagation matrices are multiplied together yielding the effective propagation matrix for the superlattice. Such an superlattice structure effectively increases the heterojunction barrier while reducing the lattice mismatch and alloy scattering.

In one embodiment, the super lattice structure may be improved by growing a specially designed superlattice heterobarrier that has a non-periodic structure. An example of one such barrier with a special increased electron reflectivity design we have developed is called a “strain-modulated aperiodic superlattice heterobarrier” (SMASH™) and will be described in further detail below.

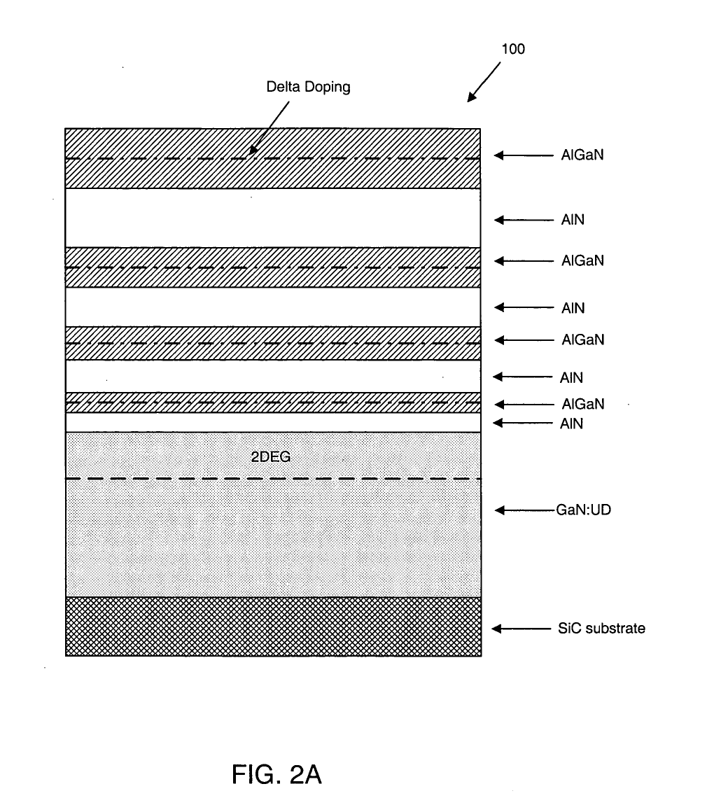

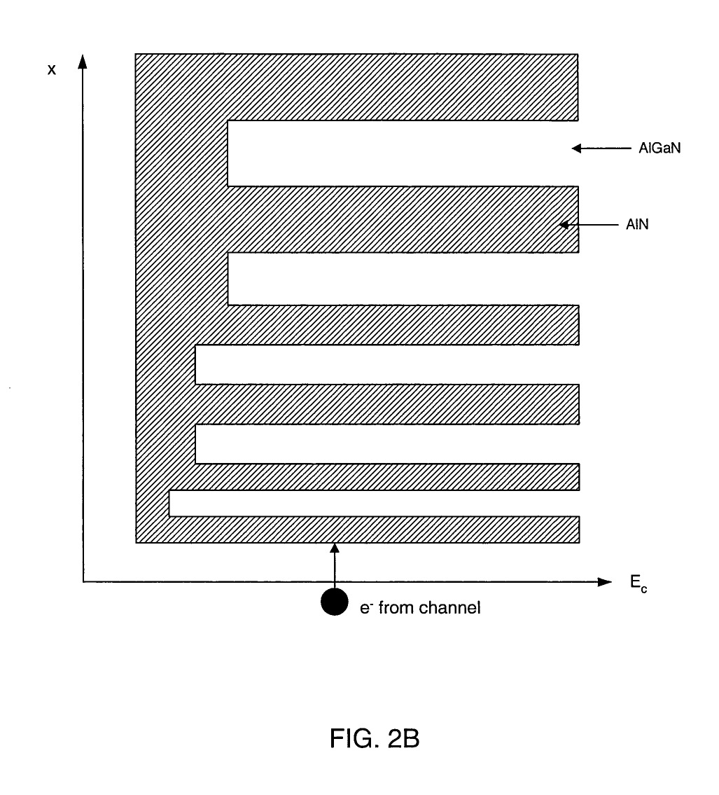

Embodiments disclosed herein include methods to improve performance of Group III-N HFET devices in terms of power, frequency response, noise and stability. Specifically, a number of HFET device structures are disclosed. For example, a first HFET device structure including delta-doped AlGaN/AlN/GaN HFETs using an ultra-thin AlN binary superlattice barrier layer is depicted in FIG. 2A. Other examples of HFET device structures include delta-doped and undoped strain-modulated aperiodic superlattice heterobarrier (SMASH) electron donor and confinement structures.

In an embodiment, a specially designed SMASH barrier may be used in an HFET device to improve carrier confinement and to reduce the leakage current for high-power devices. Such SMASH barriers may include quantum-mechanically designed barriers, which reflect electrons back into the channel. Such SMASH barriers may further provide a high carrier density from the combined effects of the piezoelectric and polarization charges and the carriers provided by delta doping. As used herein a SMASH barrier generally refers to a barrier in which successive well layers generally have an increasing band gap in the conduction band energy diagram.

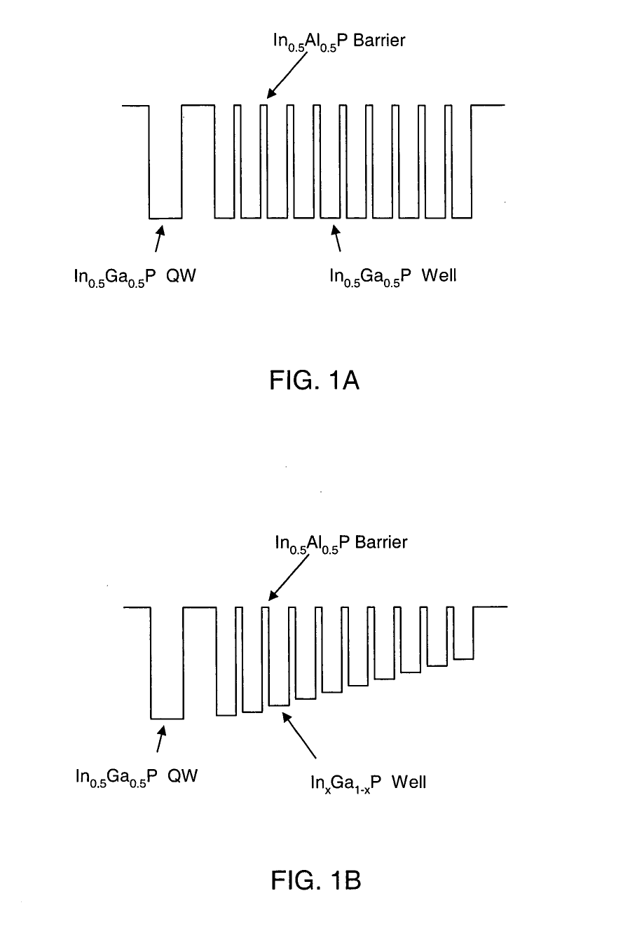

In a strain-modulated aperiodic superlattice heterobarrier, successive well layers have an increasing band gap in the conduction band energy diagram for the SMASH as shown in FIG. 1A for the InAlP/InGaP/GAAs system. A schematic drawing of the conduction band energy of a conventional multiple quantum barrier structure is shown in FIG. 1B. For the InAlP/InGaP/GaAs system, this corresponds to an increasing amount of strain in the consecutive wells of the superlattice. If a single quantum well is sandwich between a pair of SMASHs, the tendency of the electrons to thermalize into the well will be enhanced significantly because of the decreasing potential of the superlattice well layers towards the single quantum well. Once confined in the quantum well, the thermionic emission of the electrons will be greatly reduced due to the increased electron reflectivity of the SMASH. Therefore, the SMASH enhances the collection and confinement of the carriers. These arguments are confirmed both by theoretical calculations and by experimental observations.

A schematic diagram of an HFET device including a SMASH barrier is depicted in FIG. 2A, and generally referenced by numeral 100. HFET device 100 includes superlattice charge layers and at least one AlN barrier. As used herein a superlattice structure refers to a stack of repeating alternate layers.

The HFET device is formed on a substrate. Suitable substrates for the formation of an HFET include, but are not limited to c-plane (0001) Al₂O₃ (sapphire), 4H—SiC, 6H—SiC, thick AlN/sapphire, bulk GaN, AlN substrates, etc. While (0001) sapphire may be used for GaN growth because of its availability and relatively low cost, the lattice and thermal expansion coefficients are quite different from those of the Group III-N materials. It is believed that SiC has better thermal and lattice match to the Group III-N compounds, particularly to AlN, yet the crystalline quality of 6H— and 4H—SiC substrates is still not as high as sapphire. Furthermore, the surface roughness and subsurface damage for “typical” commercial SiC substrates are believed to be inferior to that of sapphire. While the cost of 2.0 in. diameter semi-insulating 4H—SiC substrates on the “open market” may be about forty times that of a 2.0 in. diameter sapphire substrate, the performance advantages of electronic devices fabricated from heteroepitaxial GaN/SiC films are documented.

In forming a device as disclosed herein, the quality of Group III-N epitaxial layers may be directly related to the quality and lattice constant of the substrate on which the Group III-N material is grown. For the growth of Group III-N epitaxial layers on sapphire or SiC substrates for high-power devices, low-pressure metalorganic chemical vapor deposition (MOCVD) or molecular-beam epitaxy (MBE) may be employed. For example, in an embodiment, GaN epitaxial layers may be grown in an EMCORE D125 reactor at pressures of ˜200 Torr. In another embodiment, a Thomas Swan Close Coupled Showerhead (CCS) MOCVD reactor system with a seven wafer capacity may be used. Other reactor systems may also be suitably used to grow such structures. AlGaN layers may be grown in the same MOCVD reactor at ˜50 Torr in order to avoid adduct formation as much as possible. Device structures may be grown in a H₂ ambient using adduct-purified trimethylgallium (TMGa) and trimethylaluminum (TMAl) as metal alkyl sources, and NH₃ as the nitrogen source. Silane (SiH₄) and bis(cyclopentadienyl)-magnesium (Cp₂Mg) may be employed as n-type and p-type dopants, respectively. Other metalorganic, hydride and dopant sources may also be used, as are known in the art. A two-temperature growth process may be employed with a low-temperature thin AlN buffer layer (BL) for SiC substrates, and with high-temperature (HT) layers grown for the device active region. The MOCVD growth of GaN on SiC may begin with a ˜100 nm high temperature (Tg˜1050° C.) AlN buffer layer, although various “graded AlGaN” conducting buffer layers have been developed for the growth of optoelectronic devices on SiC. In embodiments disclosed herein, it may be desirable to grow these layers without creating cracks in the epitaxial structure (e.g., by the use of various types of stress-relieving buffer layer structures).

In FIG. 2A, an undoped GaN layer is formed on a substrate of SiC. Undoped GaN layer may be formed from trimethyl gallium and ammonia in a MOCVD reactor at about 1050° C.

A superlattice structure may be formed on top of the undoped GaN layer. In one embodiment, a SMASH superlattice structure is formed that includes alternating layers of undoped AlN and n-type doped AlGaN layers, as depicted in FIG. 2A. In FIG. 2A, superlattice includes 8 layers of alternating AlN and AlGaN layers. AlN layers are undoped and are formed by an epitaxial growth process. The AlGaN layer is then formed on top of the AlN process, with doping of the AlGaN layer occurring by introducing SiH₄ during into the reactor during the growth process. The layers are designed to create a superlattice heterobarrier that has a non-periodic structure. FIG. 2B depicts a schematic representation of the conduction band structure of HFET device 100.

Delta-doped binary-barrier (D²B²) HFET structures, and SMASH-FETs, may have several significant features. In an embodiment, a basic D²B² HFET structure incorporates a binary AlN barrier and a delta-doped charge layer in the AlGaN near this AlN barrier. Such a structure may allow electrons to tunnel through this barrier and to enhance the free charge in the channel. Such structures may also reduce alloy scattering at the AlN—GaN interface as compared to an AlGaN—GaN interface.

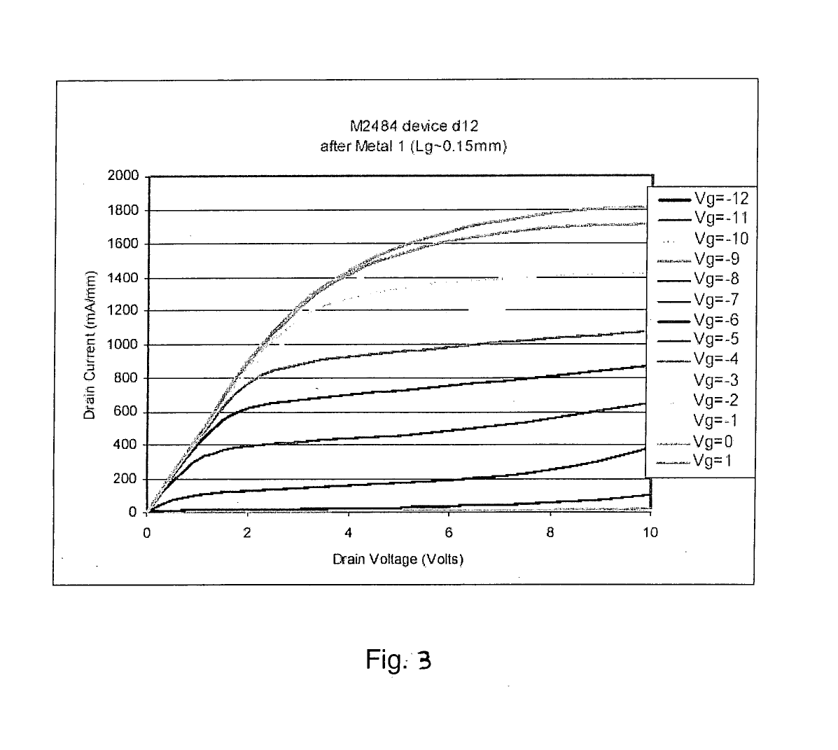

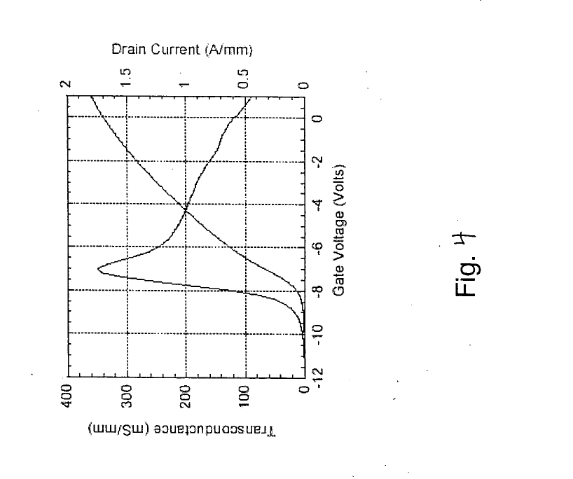

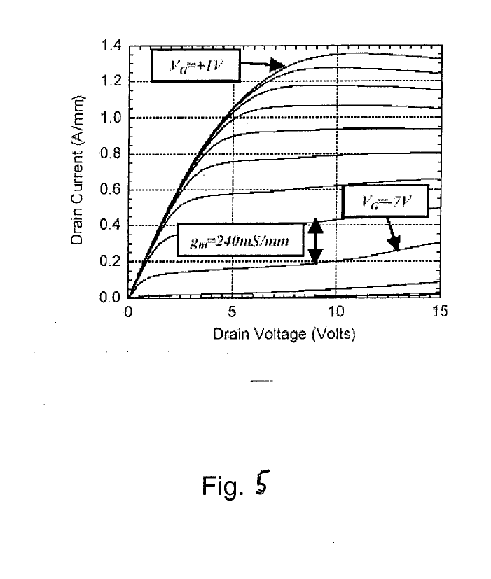

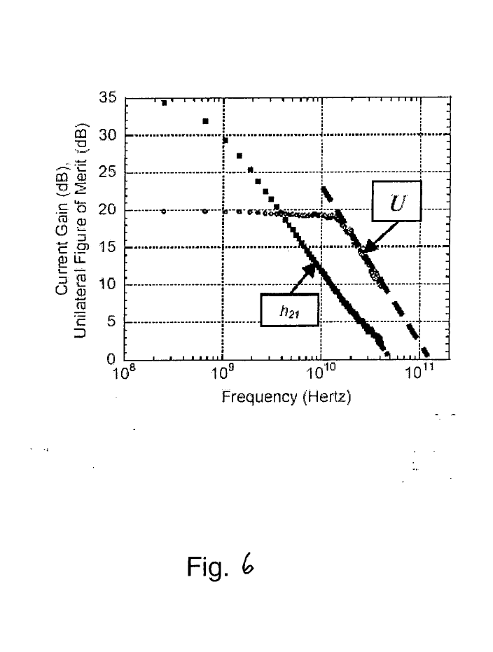

AlGaN/GaN HFETs having a gate length of 0.2-0.5 μm have been fabricated. Using the D²B² structure, improved nₛ×mobility product has been measured for electrons in the channel of an AlGaN/GaN HEMT. For example, in one experiment using a D²B² AlGaN/GaN HFET structure, including a binary AlN barrier and an AlGaN delta-doped charge layer, a two-dimensional electron gas having a carrier mobility of μₙ=1,058 cm2/V−s and a sheet carrier density of nₛ=2.35×10¹³ cm⁻² at room temperature were obtained, resulting in a nₛ μₙ product of 2.49×10¹⁶/V−s. In experiments, AlGaN/AlN/GaN HFET devices with 0.15 μm gate lengths exhibited maximum current densities as high as I_{DSmax}=1.8 A/mm at V_{G}=+1 V. FIG. 3 depicts a plot of I_{DS} vs. V_{DS} for an L_{G}=0.15 μm D²B² AlGaN/AlN/GaN HFET. FIG. 4 depicts a plot of Transconductance vs. Gate Voltage for an L_{G}=0.15 μm D²B² AlGaN/AlN/GaN HFET. FIG. 4 shows that such devices may exhibited peak transconductance of up to gₘ=350 mS/mm. FIG. 5 shows a plot of I_{DS} vs. V_{DS} for an L_{G}=0.25 μm D₂B² AlGaN/AlN/GaN HFET. FIG. 5 shows that AlGaN/AlN/GaN HFET devices with 0.25 μm gate lengths exhibited gₘ=240 mS/mm. FIG. 6 depicts frequency response data for an L_{G}=0.25 μm D²B² AlGaN/AlN/GaN HFET showing a current gain (h₂₁) and unilateral figure of merit (U) and indicating f_{T}=50 GHz and fₘₐₓ=130 GHz.

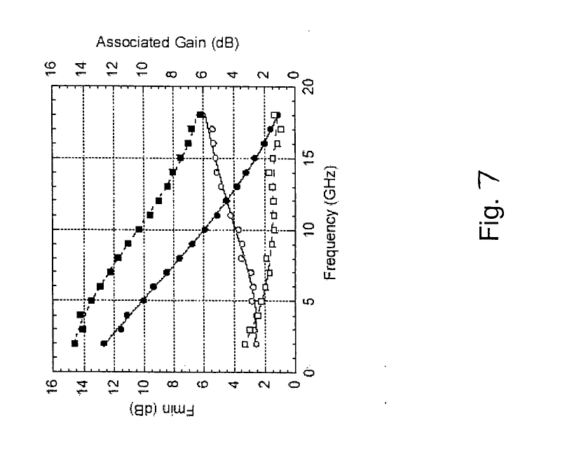

L_{G}=0.25 μm devices have demonstrated a record low-noise power for this gate length, as demonstrated in FIG. 7. FIG. 7 depicts the minimum noise figure and associated gain vs. frequency for V_{DS}=10 V and 15V. The noise characteristics of these devices have been measured to be about 1.6 dB at 10 GHz, an exceptionally low value. Noise characterization was performed for the frequency range of 2-18 GHz to determine Γₒₚₜ, the noise resistance (Rₙ), the minimum noise figure (Fₘᵢₙ), and the associated gain (Gₐ). For L_{G}=0.25 μm D²B² HFETs, a state-of-the-art minimum noise figure of Fₘᵢₙ=0.93 dB with 7 dB of associated gain was obtained at 17 GHz and at 10 GHz, the noise figure of the D²B² HFET was 1.1 dB with 10 dB associated gain. These results indicate that the D²B² structure may be compatible with high current densities, as well as with high-frequency and low-noise performance desired for X-band BMD-class receivers.

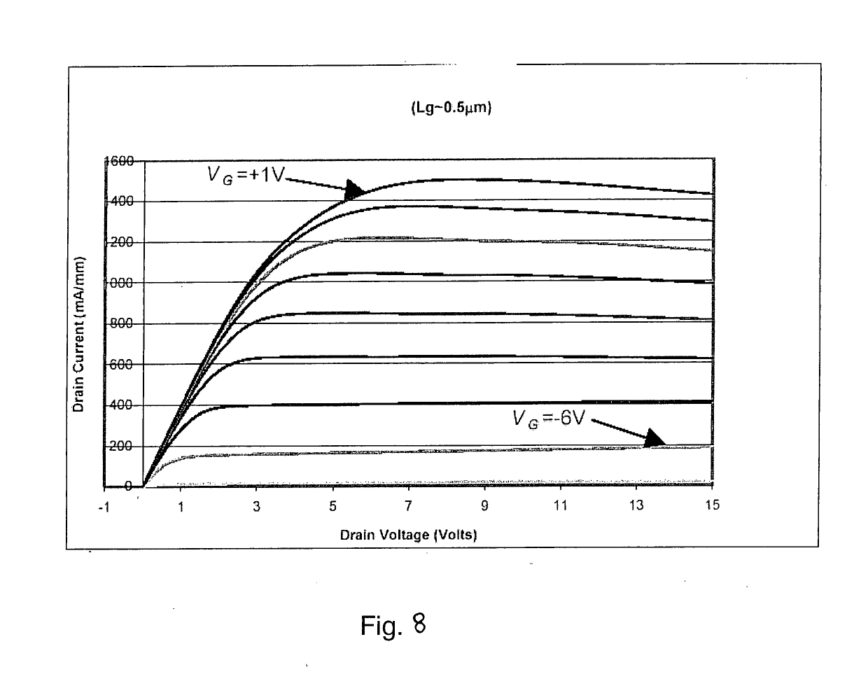

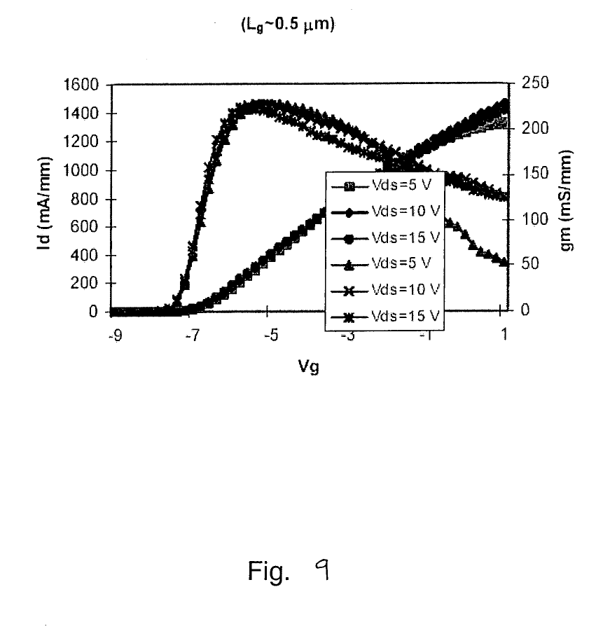

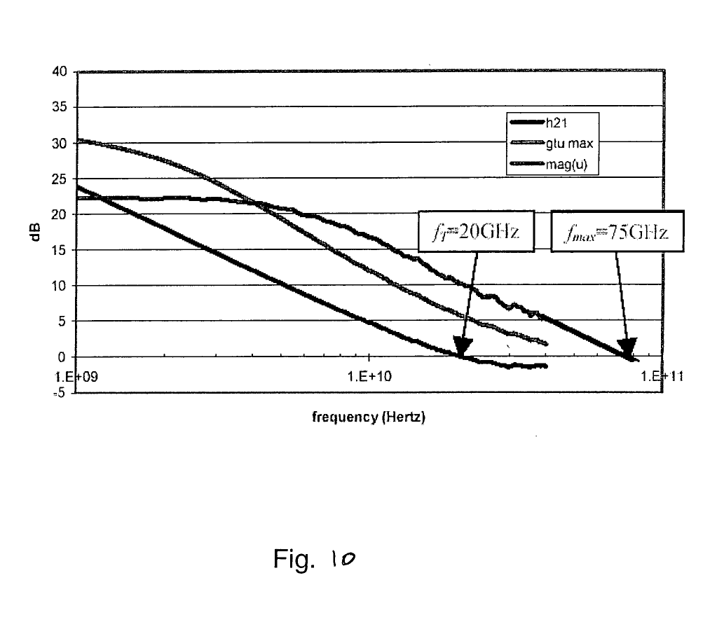

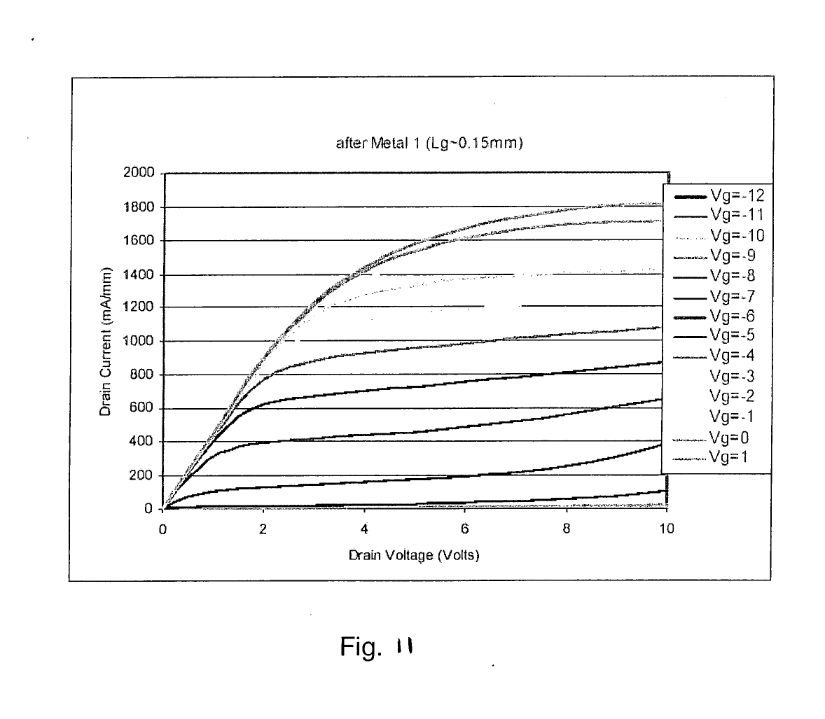

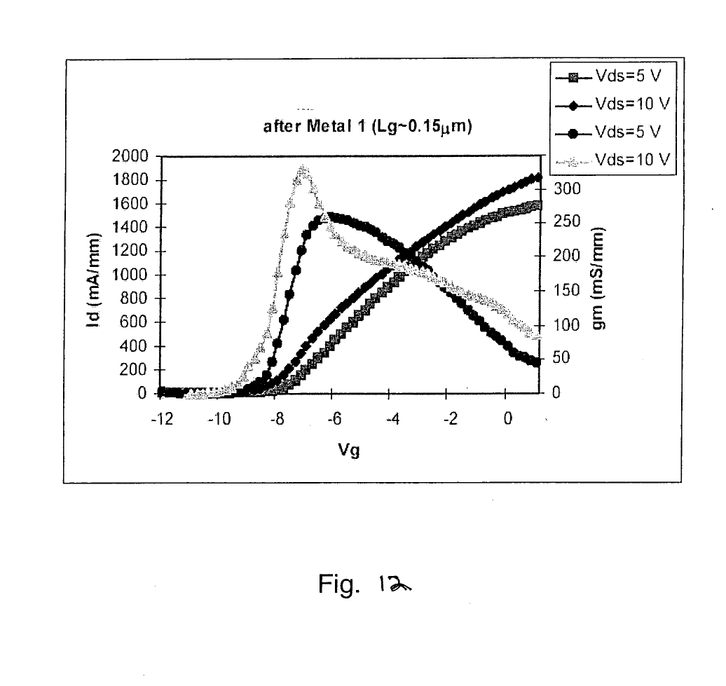

D²B² devices having gate lengths of between about L_{G}=0.15 μm and about 0.5 μm have been formed. The devices may approximate short-gate lengths (e.g., for high-frequency applications) and longer-gate lengths (e.g., for high power devices). The formed devices have been used to evaluate the performance of the materials used to form the devices. In experiments, AlGaN/AlN/GaN HFET. FIG. 8 depicts a plot of I_{DS} vs. V_{DS} for an L_{G}=0.5 μm D²B² AlGaN/AlN/GaN HFET. As shown in FIG. 8, devices with 0.5 μm gate lengths exhibited maximum current densities as high as I_{DSmax}=1.5 A/mm at V_{DS}=9 V. FIG. 9 depicts a plot of I_{DS} and gₘ vs. V_{G} for an L_{G}=0.5 μm D²B² AlGaN/AlN/GaN HFET. As shown in FIG. 9, the I_{DS}-V_{G} curves are nearly linear, corresponding to a large, relatively flat gₘ vs. V_{G} curve. The peak I_{Dsmax}=1.4 A/mm and gₘ exceeds 230 mS/mm. It is believed that these values are record numbers for the performance of AlGaN/GaN HFETs with L_{G} approximately 0.5 μm (e.g., in the range of about 0.3 to 0.7 μm). FIG. 10 shows the frequency response data for an L_{G}=0.5 μm D²B² AlGaN/AlN/GaN HFET indicating f_{T}=20 GHz and fₘₐₓ=about 75 GHz.

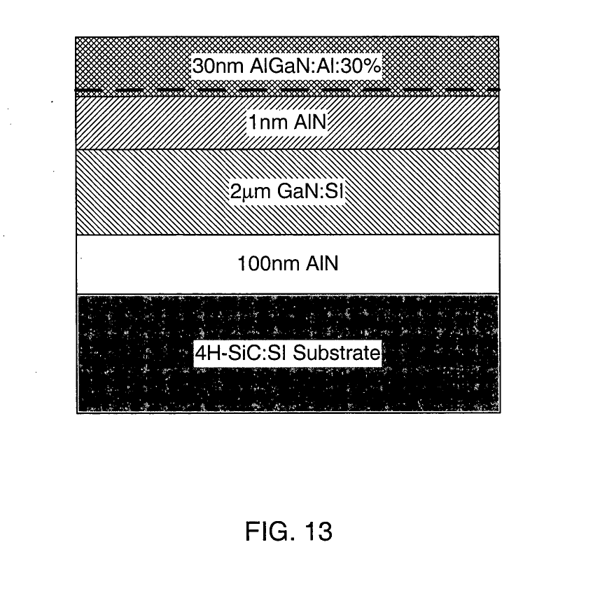

FIG. 12 depicts a plot of I_{DS} vs. V_{DS} for an L_{G}=0.15 μm D²B² AlGaN/AlN/GaN HFET after metalization. As shown in FIG. 12, devices with 0.15 μm gate lengths exhibited maximum current densities as high as I_{DSmax}>1.8 A/mm at V_{DS}=9 V. FIGS. 12 and 13, the L_{G}=0.15 μm devices exhibit even higher values of I_{DSmax} greater than 1.8 A/mm and gₘ values as high as 330 mS/mm. It is believed that these values are record numbers for the performance of AlGaN/GaN HFETs with L_{G} approximately 0.15 μm. FIG. 13 depicts a plot of I_{DS} and gₘ vs. V_{G} for an L_{G}=0.15 μm D²B² AlGaN/AlN/GaN HFET after metalization. As shown in FIG. 13, the I_{DS}-V_{G} curves at V_{DS} are nearly linear, corresponding to a large, relatively flat gₘ vs. V_{G} curve. The peak I_{Dsmax}>1.8 A/mm and gₘ exceeds 330 mS/mm.

Some known designs for high-power Group III-N gallium-nitride-based FETs employ a single AlGaN barrier layer to confine the electrons to the channel. This channel carries the current when the device is “ON.” At high currents, high-energy charge carriers may be injected into this barrier reducing the current in the channel, lowering the effective mobility, and/or reducing the effect of the gate voltage on the current flow. In certain embodiments disclosed herein, the effective energy barrier may be increased by a significant amount due to quantum-mechanical reflection of carriers. Such reflections may enhance the performance of the device by maintaining the charge in the channel even for the high-current situations. Reflection may also improve the high-frequency performance. Certain embodiments may include both a superlattice and delta doping, which may provide more free charge carriers (electrons) to the channel than a conventional doped or undoped AlGaN charge layer.

An additional embodiment of an HFET design is represented schematically in FIG. 13. FIG. 13 depicts an embodiment of an HFET that includes an AlN barrier and delta-doped charge layer. While FIG. 13 depicts a SiC substrate, it should be understood that the HFET depicted in FIG. 13 may be formed on any other type of substrate as described previously. The process of forming an HFET as depicted in FIG. 13 includes forming a buffer layer of AlN on the substrate. As shown the buffer layer may be about 100 nm in thickness. Next a Si doped GaN layer is formed, the GaN layer may be doped with SiH₄ during epitaxial growth of the layer. A binary AlN and delta-doped AlGaN layer is then formed on top of the doped GaN layer. In one embodiment, the AlN barrier is a thin (<about 5 nm) layer. The doped AlGaN layer is formed on top of the barrier layer. In one embodiment, the doped AlGaN layer has a composition of AlₓGa₁₋ₓN where x is about 0.2 to about 0.3. The AlGaN layer may be about 20 to 30 nm thick.

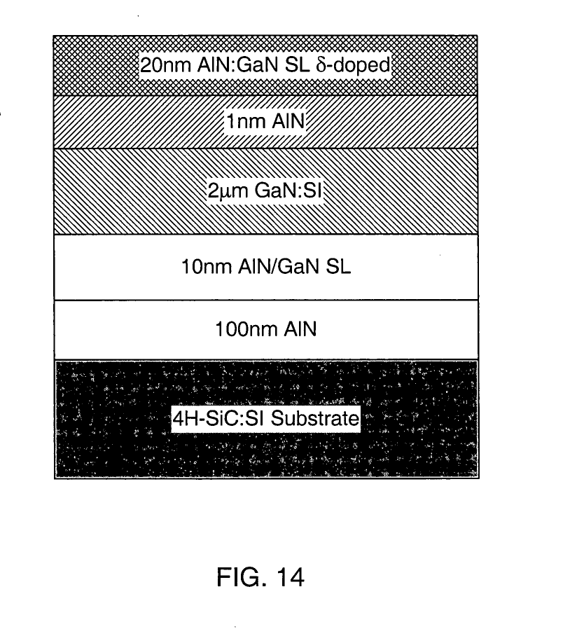

An additional embodiment of an HFET design is represented schematically in FIG. 14. FIG. 14 depicts an embodiment of an HFET that includes an AlN/GaN superlattice charge and buffer layer. While FIG. 14 depicts a SiC substrate, it should be understood that the HFET depicted in FIG. 14 may be formed on any other type of substrate as described previously. The process of forming an HFET as depicted in FIG. 14 includes forming a buffer layer of AlN on the substrate. As shown the buffer layer may be about 100 nm in thickness. An AlN/GaN superlattice buffer layer is formed. The superlattice buffer layer includes alternate layers of undoped AlN and GaN. Each of the layers may be about 2 nm or less in thickness. Next a Si doped GaN layer is formed, the GaN layer may be doped with SiH₄ during epitaxial growth of the layer. An AlN/GaN superlattice charge layer is formed on top of the doped GaN layer. The superlattice buffer layer includes alternate layers of undoped AlN and n-type doped GaN. Each of the layers may be about 2 nm or less in thickness.

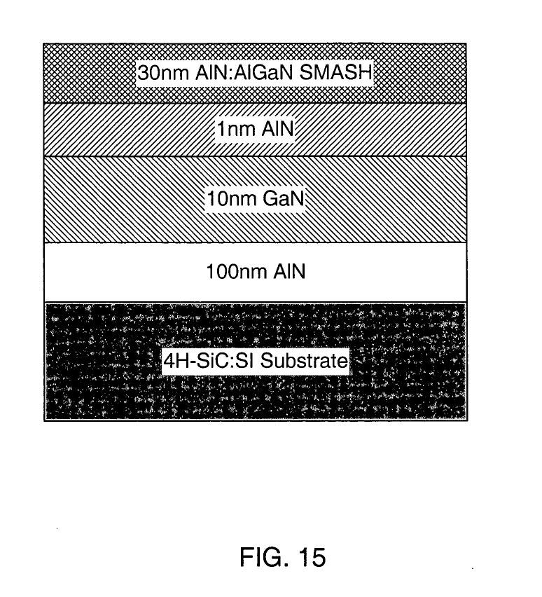

An additional embodiment of an HFET design is represented schematically in FIG. 15. FIG. 15 depicts an embodiment of an HFET that includes an AlN barrier and delta-doped charge layer. While FIG. 15 depicts a SiC substrate, it should be understood that the HFET depicted in FIG. 15 may be formed on any other type of substrate as described previously. The process of forming an HFET as depicted in FIG. 5 includes forming a buffer layer of AlN on the substrate. As shown the buffer layer may be about 100 nm in thickness. Next a thin GaN layer is formed. A thin (<5 nm) AlN barrier layer may be formed on the GaN layer. A superlattice structure may be formed on top of the undoped GaN layer. In one embodiment, a SMASH superlattice structure is formed that includes alternating layers of undoped AlN and n-type doped AlGaN layers. Doping of the AlGaN layer occurring by introducing SiH₄ during into the reactor during the growth process. The layers are designed to create a superlattice heterobarrier that has a non-periodic structure.

The HFET device performance, particularly for high-power operation, depends on many factors, including the source and drain Ohmic contact resistance. Generally, this contact is placed upon the “top” of the AlGaN “charge layer.” In some embodiments, the AlGaN layer has been selectively removed to provide a more direct contact. For n-type GaN:Si and AlGaN:Si layers, both Ti/Al/Pt/Au and Ti/Ag/Au systems may be used to form contacts. In one embodiment, an n-type Ti/Al/Pt/Au contact scheme reproducibly shows the lowest TLM specific contact resistance using a 850C/30s anneal. These n-type Ohmic contacts have a specific contact resistance to n-type GaN:Si (n−2×10¹⁸ cm ) of Rc<1×10⁻⁶Q-cm². Ohmic contact resistance to undoped AlGaN (typical of the electron barrier in HFETs) is generally higher. Recently, we have identified an new Ohmic contact scheme employing vanadium-based contacts for n-type AlGaN films which may improve Ohmic contacts to high Al-composition AlₓGal₁₋ₓN films with specific contact resistances as low as 4×10⁻⁵ Ohm-cm² for x=about 0.60 films. SiNₓ may be used as an amorphous dielectric insulator to improve the leakage characteristics and stability of the Gate for AlGaN/GaN HFETs. This film may be deposited immediately after the growth of the AlGaN charge layer in the MOCVD reactor. This “in-situ” passivation and Gate layer may provide a stable, low-leakage dielectric film to stabilize the surface charges due to the “free AlGaN” surface. It is widely known that GaN films “dissociate” during the “cool-down” process when the wafer is exposed to elevated temperatures in an H₂+NH₃ environment. AlGaN also degrades in the same way, albeit at a somewhat reduced rate. This process may be especially rapid near a screw or edge dislocation. A stable, amorphous SiNₓ film may be grown directly on the AlGaN layer-this will stabilize the AlGaN surface and inhibit the increase in leakage currents and Gate breakdown under high-stress operating conditions. The gate metal may be deposited upon this thin SiNₓ layer, creating an insulated gate structure. The in-situ SiNₓ layer may be capped with an additional plasma-enhanced chemical vapor deposition (PECVD) SiNₓ film in the regions between the Gate and the Source and the Gate and the Drain to improve the stability of the surfaces in these regions as well. The in-situ-deposited SiNₓ film may reduce the leakage contributions from these areas as well.

Cl-based inductively coupled plasma (ICP) etching may be used for the device isolation processing. This is a relatively low-damage etching process. Alternatively, wet etching with KOH solutions is known to improve the leakage current density for p-i-n diodes and may be used for device isolation etching of HFETs as well. The stability of the mesa surfaces may play a role in the operation of the device under high-power conditions.

The commonly used gate metal for an HFET is Ni/Au because it is convenient and is compatible with submicron processing. Other gate metals may be used including W or WSi.

### EXAMPLE

An unpassivated delta-doped, binary barrier (D²B²) HFET device with 0.15 μm-gate length was formed. The AlₓGa₁₋ₓN/GaN (x≈0.2, 1.0) heterostructures of this work were grown by low-pressure metalorganic chemical vapor deposition (MOCVD) in an EMCORE TurboDisc D125 UTM high-speed rotating-disk reactor on 2.0 in. diameter 4H semi-insulating SiC substrates. The GaN epitaxial layer is grown at pressures of about 200 Torr and the AlGaN epitaxial layers are grown at about 50 Torr in a hydrogen ambient using adduct-purified trimethyl gallium (TMGa), trimethylaluminum (TMAl), and ammonia (NH₃). Silane (SiH₄) was used for the n-type dopant. The growth process begins with a high-temperature (about 1070° C.) AlN buffer layer, 100 nm in thickness. The subsequent device layers are grown at about 1050° C., beginning with 3 μm of undoped GaN. On top of this is a 1 nm AlN barrier layer, followed by a 30 nm layer of AlₓGa₁₋ₓN (x is about 0.2). The delta doping occurs after 5 nm of growth of this last layer, with an expected Si dopant concentration >1×10¹⁹ cm⁻³ (as measured by secondary ion mass spectroscopy (SIMS) analysis on similarly doped structures). Room-temperature Hall-effect measurements yield an electron mobility of 1,066 cm²/V−s and a sheet carrier density of 2.30×10¹³ cm⁻², resulting in a large nₛμ product of 2.45×10¹⁶/V−s. This is a large improvement over a similar structure without the barrier layer and delta doping: Hall results were 1,308 cm²/V−s, 1.18×10¹³ cm⁻², and 1.54×10¹⁶ V−s, for mobility, sheet charge, and nₛμ product, respectively. Variable-temperature Hall-effect measurements were also performed over the temperature range from 77 K to 290 K. The sheet carrier density remained fairly constant over the measured temperature range, while the mobility steadily increased for lower temperatures, indicating that the 2DEG dominated the electrical transport characteristics.

D²B² HFET devices were then fabricated from the epitaxial heterostructures. Using chlorine as the active species, a dry etch to a depth of 250 nm was performed for device isolation. A metallization scheme consisting of Ti/Al/Ti/Au was deposited by a conventional lift-off process and rapid thermal annealed at 950° C. to obtain Ohmic contacts. From standard TLM measurements, the contact resistance was calculated to range from 0.68 to 0.87 Ohms-mm. The Ni/Au Schottky-barrier T-gate was defined by electron-beam lithography with a tri-layer resist structure (5.5% PMMA/8.5% P(MMA-MAA)/4% PMMA). HFET devices with gate lengths of 0.5 μm and 0.15 μm have been fabricated to investigate power device performance and high-frequency performance, respectively. The standard device has two parallel gate fingers, with a gate width of 75 μm. No passivation has been used for the devices reported here.

References:

The following references are hereby incorporated by reference as though fully set forth herein:
1) L. Shen, S. Heikman, B. Moran, R. Coffie, N. Q. Zhang, D. Buttari, I. P. Smorchkova, S. Keller, S. P. DenBaars and U. K. Mishra, IEEE Electron Device Lett. 22,457 (2001).
2) A. Ping, E. Piner, J. Redwing, M. Khan, and I. Adesida, Electron. Lett. 36, 175 (2000).
3) W. Lu, J. Yang, M. Khan, and I. Adesida, IEEE Trans. Elect. Dev. 48, 581 (2001).
4) K. J. Schoen, J. M. Woodall, J. A. Cooper, and M. R. Melloch, IEEE Trans. Electron. Dev. 45, 1595 (1998).
5) M. Trivedi, and K. Shenai, J. Appl. Phys. 85, 6889 (1999).
6) Q. Wahab, T. Kimoto, A. Ellison, C. Hallin, M. Tuominen, R. Yakimova, A. Henry, J. P. Bergman, and E. Janzen, Appl. Phys. Lett. 72, 445 (1998).
7) K. G. Irvire, R. Singh, M. J. Paisley, J. W. Palmour, O. Kordina, and C. H. Carter, Jr., Mat. Res. Soc. Symp. Proc. 512, 119 (1998).
8) Z. Z. Bandic, P. M. Bridger, E. C. Piqutte, T. C. McGill, R. P. Vaudo, V. M. Phanse, and J. M. Redwing, Appl. Phys. Lett. 74, 1266 (1999).
9) G. T. Dang, A. P. Zhang, F. Ren, X. A. Cao, S. J. Pearton, H. Cho, J. Han, J. I. Chyi, C. M. Lee C. C. Chuo, S. N. G. Chu, R. G. Wilson, IEEE Trans. Electron Dev. 47, 692 (2000).
10) F. Ren, A. P. Zhang, G. T. Dang, X. A. Cao, H. Cho, S. J. Pearton, J. I. Chyi, C. M. Lee, and C. C. Chuo, Sol. State Electron. 44, 619 (2000).
11) T. G. Zhu, D. J. H. Lambert, B. S. Shelton, M. M. Wong, U. Chowdhury and R. D. Dupuis, “High-Voltage GaN Vertical p-i-n Rectifier with a 2 μm-Thick i-Layer,” Electron. Lett. 36, 1971 (2000).
12) V. Tilak, B. Green, V. Kaper, H. Kim, T. Prunty, J. Smart, J. Shealy and L. Eastman, IEEE Electron Devices Lett. 22, 504 (2001)
13) Y. F. Wu, D. Kapolnek, J. P. Ibbetson, P. Parikh, B. P. Keller and U. Y. Mishra, IEEE Trans. Elect. Devices 48, 586 (2001)
14) A. T. Ping, Q. Chen, J. W. Yang, M. A. Khan and I. Adesida, IEEE Electron Device Lett. 19, 54 (1998).
15) A. Vescan, R. Dietrich, A. Wieszt, A. Schurr, H. Leier, E. L. Piner and J. M. Redwing, Elect. Lett. 36, 1234 (2000).
16) Y. F. Wu, D. Kapolnek, J. lbbetson, N. Q. Zhang, P. Parikh, B. P. Keller and U. K. Mishra, 1999 IEDM Tech. Dig., IEEE Press, Piscataway, N.J., 1999, pp. 925-927.
17) S. T. Sheppard, K. Doverspike, W. L. Pribble, S. T. Allen, J. W. Palmour, L. T. Kehias, and T. J. Jenkins, IEEE Electron. Dev. Lett. 20, 160 (1999).

In this patent, certain publications have been incorporated by reference. The text of such publications is, however, only incorporated by reference to the extent that no conflict exists between such text and the other statements and drawings set forth herein. In the event of such conflict, then any such conflicting text in such incorporated by reference publications is specifically not incorporated by reference in this patent.

While the present invention has been described with reference to particular embodiments, it will be understood that the embodiments are illustrated and that the invention scope is not so limited. Any variations, modifications, additions and improvements to the embodiments described are possible. These variations, modifications, additions and improvements may fall within the scope of the invention as detailed within the following claims.

1. A field-effect transistor comprising:
a substrate;
an undoped GaN layer formed on the substrate; and
a superlattice structure formed on the undoped GaN layer, wherein the superlattice structure comprises alternating layers of a barrier layer of AlN and a doped layer of AlGaN.

2. The transistor of claim 1, wherein the substrate comprises SiC.

3. The transistor of claim 1, wherein the substrate comprises sapphire.

4. The transistor of claim 1, further comprising an AlN buffer layer disposed between the substrate and the first layer.

5. The transistor of claim 1, wherein the doped AlGaN layer is an n-type doped layer.

6. The transistor of claim 1, wherein the doped layer AlGaN layer is an n-type doped layer, and wherein the doping comprises Si.

7. The transistor of claim 1, wherein the doped layer comprises AlₓGa₁₋ₓN, where x is from 0.2 to about 0.3.

8. The transistor of claim 1, wherein the superlattice structure comprises a strain-modulated aperiodic superlattice heterobarrier.

9. A method of making a field-effect transistor comprising:
forming an undoped GaN layer on a substrate;
forming a superlattice structure on the undoped GaN layer, wherein the superlattice structure comprises alternating layers of a barrier layer of AlN and a doped layer of AlGaN.

10. The method of claim 9, wherein the substrate comprises SiC.

11. The method of claim 9, wherein the substrate comprises sapphire.

12. The method of claim 9, further comprising forming an AlN layer between the substrate and the GaN layer.

13. The method of claim 9, wherein the doped AlGaN layer is an n-type doped layer.

14. The method of claim 9, wherein the doped layer AlGaN layer is an n-type doped layer, and wherein the doping comprises Si.

15. The method of claim 9, wherein the doped layer comprises AlₓGa₁₋ₓN, where x is from 0.2 to about 0.3.

16. The method of claim 9, wherein the superlattice structure is formed as a strain-modulated aperiodic superlattice heterobarrier.

17. A field-effect transistor comprising:
a substrate;
a doped GaN layer formed on the substrate;
an AlN barrier layer formed on the doped GaN layer; and
a doped layer of AlGaN formed on the AlN barrier layer.

18. The transistor of claim 17, wherein the substrate comprises SiC.

19. The transistor of claim 17, wherein the substrate comprises sapphire.

20. The transistor of claim 17, further comprising an AlN buffer layer disposed between the substrate and the first layer.

21. The transistor of claim 17, wherein the doped AlGaN layer is an n-type doped layer.

22. The transistor of claim 17, wherein the doped layer AlGaN layer is an n-type doped layer, and wherein the doping comprises Si.

23. The transistor of claim 17, wherein the doped layer comprises AlₓGa₁₋ₓN, where x is from 0.2 to about 0.3.

24. A method of making a field-effect transistor comprising:
forming a doped GaN layer on a substrate;
forming an AlN barrier layer on the doped GaN layer; and
forming a doped layer of AlGaN on the AlN barrier layer.

25. The method of claim 24, wherein the substrate comprises SiC.

26. The method of claim 24, wherein the substrate comprises sapphire.

27. The method of claim 24, further comprising forming an AlN layer between the substrate and the GaN layer.

28. The method of claim 24, wherein the doped AlGaN layer is an n-type doped layer.

29. The method of claim 24, wherein the doped layer AlGaN layer is an n-type doped layer, and wherein the doping comprises Si.

30. The method of claim 24, wherein the doped layer comprises AlₓGa₁₋ₓN, where x is from 0.2 to about 0.3.

31. A field-effect transistor comprising:
a substrate;
a first superlattice structure, wherein the first superlattice structure comprises alternating layers of AlN and GaN;
a doped GaN layer formed on the first superlattice structure; and
a second superlattice structure formed on the doped GaN layer, wherein the second superlattice structure comprises alternating layers of a barrier layer of AlN and doped AlGaN.

32. The transistor of claim 31, wherein the substrate comprises SiC.

33. The transistor of claim 31, wherein the substrate comprises sapphire.

34. The transistor of claim 31, further comprising an AlN buffer layer disposed between the substrate and the first superlattice structure.

35. The transistor of claim 31, wherein the doped AlGaN layer is an n-type doped layer.

36. The transistor of claim 31, wherein the doped layer AlGaN layer is an n-type doped layer, and wherein the doping comprises Si.

37. The transistor of claim 31, wherein the doped layer comprises AlₓGa₁₋ₓN, where x is from 0.2 to about 0.3.

38. A method of making a field-effect transistor comprising:
forming a first superlattice structure on a substrate, wherein the first superlattice structure comprises alternating layers of AlN and GaN;
forming a doped GaN layer on the first superlattice structure; and
forming a second superlattice structure on the doped GaN layer, wherein the second superlattice structure comprises alternating layers of a barrier layer of AlN and doped AlGaN.

39. The method of claim 38, wherein the substrate comprises SiC.

40. The method of claim 38, wherein the substrate comprises sapphire.

41. The method of claim 38, further comprising forming an AlN layer between the substrate and the first superlattice structure.

42. The method of claim 38, wherein the doped AlGaN layer is an n-type doped layer.

43. The method of claim 38, wherein the doped layer AlGaN layer is an n-type doped layer, and wherein the doping comprises Si.

44. The method of claim 38, wherein the doped layer comprises AlₓGa₁₋ₓN, where x is from 0.2 to about 0.3.

45. A transistor comprising a plurality of layers on a substrate, wherein a portion of the layers comprise combinations of nitrogen with one or more elements selected from group III of the periodic table to form a strain-modulated aperiodic superlattice heterobarrier, and wherein one or more of the layers comprises an AlN barrier layer.

46. The transistor of claim 45 further comprising at least one delta doped region in at least one of the layers.

47. A method of forming a transistor comprising:
providing a substrate; and
depositing a plurality of layers on the substrate, wherein a portion of the layers comprise combinations of nitrogen with one or more elements selected from group III of the periodic table to form a strain-modulated aperiodic superlattice heterobarrier, and wherein one or more of the layers comprises an AlN barrier layer.

48. The method of claim 47, further comprising, delta-doping at least one of the layers.
